(19) United States
(12) Patent Application Publication
(10) Pub. No.: US 2023/0223731 A1
(43) Pub. Date: Jul. 13, 2023

(54) OPTICAL PUMP SOURCE OUTPUT POWER AND HEALTH MONITORING

(71) Applicant: Lumentum Operations LLC, San Jose, CA (US)

(72) Inventors: Ali SALEHIOMRAN, Gatineau (CA); Vlatko MILINKOVIC, Ottawa (CA); Kim-Tuyen HOANG, Ottawa (CA)

(21) Appl. No.: 17/707,258

(22) Filed: Mar. 29, 2022

Related U.S. Application Data
(60) Provisional application No. 63/298,806, filed on Jan. 12, 2022.

(51) Int. Cl. H01S 3/091; H01S 3/067; H01S 3/0941; H01S 3/094

(52) U.S. Cl. CPC H01S 3/0912; H01S 3/06754; H01S 3/0941; H01S 3/094003

(57) ABSTRACT

In some implementations, a device may apply a modulation to an electrical current to derive a modulated electrical current. The device may supply the modulated electrical current to an optical pump source for an optical amplifier to cause the optical pump source to emit light based on the modulated electrical current. The device may generate a signal based on an optical power of the light emitted by the optical pump source. The device may filter the signal with respect to a feedback signal that is to result from the modulated electrical current to derive a filtered signal. The device may process the filtered signal to identify whether the feedback signal is present in the filtered signal based on a power indicated by the filtered signal. Whether the feedback signal is present indicates a state of the optical pump source.

### CROSS-REFERENCE TO RELATED APPLICATION

This Patent Application claims priority to U.S. Provisional Patent Application No. 63/298,806, filed on Jan. 12, 2022, and entitled “INDIRECT LASER DIODE HEALTH MONITORING AND OUTPUT POWER MEASUREMENT.” The disclosure of the prior Application is considered part of and is incorporated by reference into this Patent Application.

### TECHNICAL FIELD

The present disclosure relates generally to optical amplifiers and to output power monitoring and/or health monitoring for an optical pump source.

### BACKGROUND

An optical amplifier is a device that is to receive signal light and generate amplified signal light (i.e., signal light with comparatively higher optical power). Typically, the optical amplifier provides optical amplification using a so-called gain medium, which is “pumped” (i.e., provided with energy) by a source, such as a pump laser. In some cases, the optical amplifier may utilize an optical fiber as a gain medium (such a device may be referred to as a fiber amplifier). In such a case, the gain medium may be a glass fiber doped with rare earth ions, such as erbium, neodymium, ytterbium, praseodymium, thulium, or the like. Such a fiber may be referred to as an active fiber. In operation, the signal light propagates through the active fiber together with pump light, and the active fiber outputs the amplified signal light that is generated from the signal light and the pump light. Generally, such optical amplifiers include other discrete components associated with controlling, enabling, and/or monitoring optical amplification. Such discrete components may include, for example, one or more isolators, a combiner (e.g., a wavelength division multiplexer (WDM)), a tunable filter, a tap, a photo diode, or the like.

### SUMMARY

In some implementations, an optical amplifier system includes a rare-earth doped fiber amplifier (RDFA); an optical pump source having a first end and a second end opposite the first end, where the optical pump source is to emit light via the first end and the second end based on a modulated electrical current supplied to the optical pump source, and where the first end of the optical pump source is optically coupled to the RDFA; a detection component having a photodetector optically coupled to the second end of the optical pump source and a filter connected to the photodetector, where the photodetector is configured to generate a signal based on light that is to be emitted via the second end of the optical pump source, and the filter is configured to output a filtered signal by filtering the signal from the photodetector with respect to a feedback signal that is to result from the modulated electrical current; and a feedback component configured to identify whether the feedback signal is present in the filtered signal based on a power indicated by the filtered signal, where whether the feedback signal is present indicates a state of the optical pump source.

In some implementations, an optical amplifier system includes at least one optical amplifier; a plurality of optical pump sources optically coupled to the at least one optical amplifier, where the plurality of optical pump sources are configured to emit light based on modulated electrical currents respectively supplied to the plurality of optical pump sources; a plurality of detection components respectively optically coupled to the plurality of optical pump sources, where a detection component, of the plurality of detection components, includes a photodetector optically coupled to an optical pump source, of the plurality of optical pump sources, and a filter connected to the photodetector, where the photodetector is configured to generate a signal based on light that is to be emitted via the optical pump source, and the filter is configured to output a filtered signal by filtering the signal with respect to a feedback signal that is to result from a modulated electrical current supplied to the optical pump source; and at least one feedback component configured to identify respective states of the plurality of optical pump sources based on filtered signals output by respective filters of the plurality of detection components.

In some implementations, a method includes applying, by a device, a modulation to an electrical current to derive a modulated electrical current; supplying, by the device, the modulated electrical current to an optical pump source for an optical amplifier to cause the optical pump source to emit light based on the modulated electrical current; generating, by the device using a photodetector, a signal based on an optical power of the light emitted by the optical pump source; filtering, by the device using a filter, the signal with respect to a feedback signal that is to result from the modulated electrical current to derive a filtered signal; and processing, by the device, the filtered signal to identify whether the feedback signal is present in the filtered signal based on a power indicated by the filtered signal, where whether the feedback signal is present indicates a state of the optical pump source.

### BRIEF DESCRIPTION OF THE DRAWINGS

FIG. 1 is a diagram of an example optical amplifier system described herein.

FIG. 2 is a diagram of an example plot showing a relationship between optical pump source power and tone power described herein.

FIG. 3 is a flowchart of an example process relating to monitoring an optical pump source.

### DETAILED DESCRIPTION

The following detailed description of example implementations refers to the accompanying drawings. The same reference numbers in different drawings may identify the same or similar elements.

An optical amplifier, such as a rare-earth doped fiber amplifier (RDFA), may be pumped optically using one or more optical pump sources, such as one or more laser diodes. In some arrangements, a laser diode may deliver light directly to the optical amplifier in order to improve an efficiency of optical pumping. However, this may inhibit the evaluation of characteristics of the laser diode, such as whether the laser diode is operational or has failed, an output power of the laser diode, a performance shift of the laser diode, or the like, as light emitted from the laser diode (e.g., from a front facet of the laser diode) cannot be directly monitored.

In some cases, a photodiode may be optically coupled to a back facet of the laser diode for monitoring characteristics of the laser diode based on light exiting the back facet (such monitoring may be referred to as a back-facet monitoring (BFM)). However, a signal of the laser diode may be relatively weak at the back facet of the laser diode. Moreover, when the laser diode is operating at low output power near a lasing threshold current for the laser diode, detection of the signal over noise may be difficult (e.g., a signal-to-noise ratio (SNR) is relatively low at the back facet). As a result, back-facet monitoring of the laser diode cannot reliably detect a failure of the laser diode, an output power of the laser diode, or the like, particularly when the laser diode is operating at low output power.

Some implementations described herein provide an optical amplifier system that includes an optical amplifier, an optical pump source for the optical amplifier, a detection component optically coupled to the optical pump source and configured to monitor an optical signal of the optical pump source using a photodetector, and/or a feedback component configured to process a signal from the detection component. The detection component may be configured to indirectly monitor an output power of the optical pump source (e.g., using back-facet monitoring).

The optical amplifier system may be configured to apply a particular modulation to a driving current for the optical pump source. The modulated driving current may cause light emission from the optical pump source in accordance with the modulated driving current. Thus, a signal produced by the photodetector monitoring the optical pump source may include a particular feedback signal resulting from the modulated driving current. The detection component may be configured to filter the signal of the photodetector with respect to the feedback signal. Filtering the signal in this way may remove noise from the signal and enable detection of the feedback signal. In particular, an SNR of the filtered signal may be greater than an SNR of the signal prior to filtering, thereby enabling reliable detection of the feedback signal even when the optical pump source is operating at low output power.

In some implementations, the feedback component may compare a power indicated by the filtered signal to a threshold, thereby indicating the presence of the feedback signal if the power satisfies the threshold or the absence of the feedback signal if the power does not satisfy the threshold. The presence of the feedback signal may indicate that the optical pump source is operational, and the absence of the feedback signal may indicate that the optical pump source has failed. Moreover, the power of the feedback signal may indicate an optical power of the optical pump source. In this way, the feedback signal facilitates improved monitoring of the health and optical power of the optical pump source, particularly when the optical pump source is operating at low output power.

In some implementations, the optical amplifier system may include multiple optical pump sources and multiple detection components for respectively monitoring the multiple optical pump sources. Here, the optical amplifier system may be configured to apply a particular modulation to respective driving currents for the multiple optical pump sources, in a similar manner as described above. Moreover, as described above, a detection component for monitoring a particular optical pump source may include a photodetector that is optically coupled to the particular optical pump source. The presence of a particular feedback signal in a signal produced by the photodetector may indicate that the particular optical pump source is operational, and the absence of the feedback signal may indicate that the particular optical pump source has failed. Thus, the optical amplifier system facilitates individual monitoring of the multiple optical pump sources.

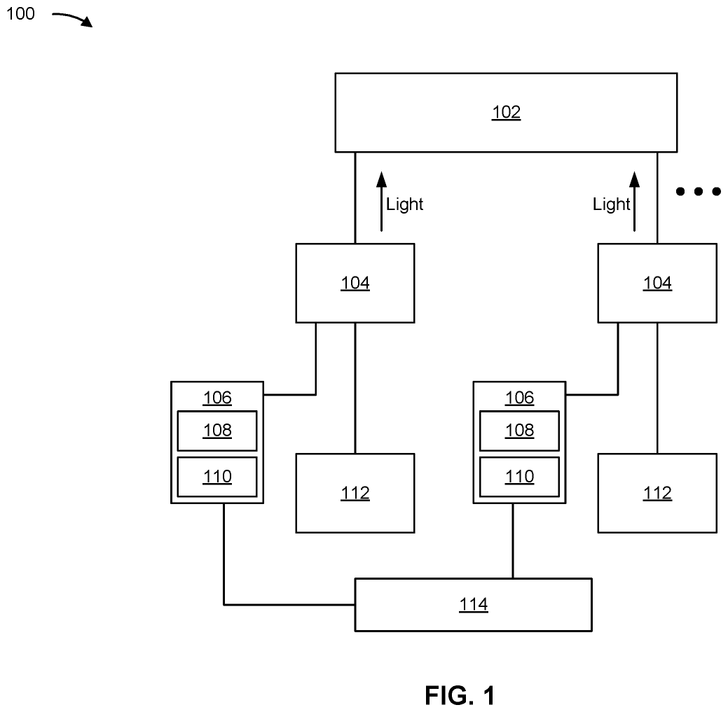

FIG. 1 is a diagram of an example optical amplifier system 100. As shown in FIG. 1, the optical amplifier system 100 may include an optical amplifier 102, an optical pump source 104, a detection component 106, a driver component 112, and/or a feedback component 114.

The optical amplifier 102 may include a gain medium that is to be optically pumped to provide optical amplification. In some implementations, the optical amplifier 102 may include an RDFA (e.g., one or more RDFAs). For example, the optical amplifier 102 may include an erbium-doped fiber amplifier (EDFA). In some implementations, the optical amplifier 102 may include an optical parametric amplifier, a Raman amplifier, and/or another type of optical amplifier that is optically pumped. In some implementations, the optical amplifier system 100 may include one or more optical amplifiers 102.

The optical pump source 104 may be configured to provide optical pumping of the optical amplifier 102. The optical pump source 104 may include a laser diode. The laser diode may be edge emitting, vertically emitting, or the like. The laser diode may have a wavelength of 980 nanometers (nm), 1480 nm, or the like. The optical pump source 104 may have a first end a second end opposite the first end. For example, for an edge-emitting laser diode, the first end may be a front facet of the laser diode and the second end may be a back facet of the laser diode. The optical pump source 104 may be configured to emit light via the first end and the second end (e.g., a reflectivity of the second end may be higher than a reflectivity of the first end, such that an optical power of light emitted from the first end is greater than an optical power of light emitted from the second end). The optical pump source 104 may be configured to emit light (e.g., via the first end and the second end) based on a modulated electrical current supplied to the optical pump source 104, as described herein.

The optical pump source 104 may be optically coupled to the optical amplifier 102. For example, the optical pump source 104 may be optically coupled directly to the optical amplifier 102 (e.g., by an optical fiber). That is, the first end of the optical pump source 104 may be optically coupled directly to the optical amplifier 102. In other words, there may be no intervening components between the optical pump source 104 and the optical amplifier 102.

The driver component 112 may be configured to supply an electrical current to the optical pump source 104. The driver component 112 may include a circuit for driving (e.g., supplying current to) an optical load (e.g., the optical pump source 104). In some implementations, the driver component 112 may include an electrical source that may provide an electrical input (e.g., current) of the driver component 112.

In some implementations, the optical amplifier system 100 may be configured to apply a modulation to the electrical current to derive a modulated electrical current and be configured to supply the modulated electrical current to the optical pump source 104 to cause the optical pump source 104 to emit light based on the modulated electrical current. The modulation applied to the electrical current may be in addition to different modulation for stabilization that is applied to the driving current. For example, the modulation for stabilization that is applied to the driving current may be to achieve (and maintain) a particular optical power level for the optical pump source 104. Moreover, the modulation may have no impact on pumping of the optical amplifier 102 by the optical pump source 104. For example, fast modulation may be transparent to the optical amplifier 102, as the optical amplifier 102 is responsive to an average current value. In some implementations, the modulation that is applied to the electrical current may be the modulation for stabilization, provided that such modulation has identifiable characteristics.

The electrical current may be modulated before reaching the driver component 112, at the driver component 112, and/or after exiting the driver component 112. In some implementations, the optical amplifier system 100 may include a signal modulator device for applying the modulation to the electrical current. In some implementations, the feedback component 114, described herein, or another controller may apply the modulation to the electrical current.

The electrical current may be modulated using a periodic signal (e.g., a waveform) with a definite period. For example, the modulation applied to the electrical current may include a sinusoidal amplitude modulation, a pulse width modulation, a frequency modulation, or the like. In some implementations, the electrical current may be modulated using an aperiodic signal or an otherwise arbitrary signal (as any modulation has a dominant harmonic that can be detected). In some implementations, the modulation applied to the electrical current may include multiple harmonic signals.

The detection component 106 may be optically coupled to the optical pump source 104. For example, the detection component 106 may be optically coupled to the second end (e.g., the back facet) of the optical pump source 104. The detection component 106 may be configured to monitor an optical signal of the optical pump source 104. For example, the detection component 106 may include a photodetector 108. Thus, the photodetector 108 may be optically coupled to the optical pump source 104 (e.g., to the second end of the optical pump source 104). In particular, the photodetector 108 may be configured to detect light exiting from the second end (e.g., the back facet) of the optical pump source 104. In other words, the photodetector 108 may be configured for back-facet monitoring of the optical pump source 104.

The photodetector 108 may include a photo diode or another device that can detect optical power. Moreover, the photodetector 108 may be configured to generate a signal (e.g., an electrical signal) that is based on a detected optical power of light emitted from the optical pump source 104 (e.g., light exiting the second end of the optical pump source 104). Based on the modulated electrical current for the optical pump source 104, an optical signal of the optical pump source 104, and thus the signal from the photodetector 108, may include at least one feedback signal (e.g., one or more dominant tones at a particular frequency). That is, the signal from the photodetector 108 may include a particular feedback signal (e.g., one or multiple particular tones) based on the particular modulation applied to the electrical current that is supplied to the optical pump source 104.

The detection component 106 may be configured to output a filtered signal by filtering, or otherwise processing, the signal from the photodetector 108. The detection component 106 may filter the signal from the photodetector 108, with respect to the feedback signal that is to result from the modulated electrical current, to derive a filtered signal. For example, filtering of the signal from the photodetector 108 may be centered around a frequency associated with the feedback signal. A first signal-to-noise ratio (SNR) associated with the filtered signal may be greater than a second SNR associated with the signal (e.g., filtering the signal may remove noise).

To filter the signal from the photodetector 108 with respect to the feedback signal, the detection component 106 may be configured to pass a range of frequencies that includes a frequency of the feedback signal (and attenuate frequencies outside of the range). For example, the detection component may include a filter 110 that is connected to the photodetector 108. The filter 110 may include a band-pass filter configured to pass the range of frequencies that includes the frequency of the feedback signal. That is, the filter 110 may be centered around the frequency of the feedback signal that is to result from the modulated electrical current. Moreover, the band-pass filter may be a narrow band-pass filter (e.g., a bandwidth of the passband may be less than or equal to 10% of the resonant frequency).

The feedback component 114 may be configured to receive the filtered signal from the detection component 106. The feedback component 114 may be configured to identify whether the feedback signal is present in the filtered signal based on a power indicated by the filtered signal. For example, the feedback component 114 may be configured to process the filtered signal to identify whether the feedback signal is present in the filtered signal based on the power indicated by the filtered signal. To identify whether the feedback signal is present in the filtered signal, the feedback component 114 may be configured to compare the power indicated by the filtered signal to a threshold (e.g., a value of the threshold may be based on the particular configuration of the optical amplifier system 100). Here, the power indicated by the filtered signal satisfying (e.g., being greater than) the threshold may indicate the presence of the feedback signal.

Moreover, whether the feedback signal is present may indicate a state of the optical pump source 104. The state may be an operational state or a failure state. For example, the feedback component 114 may be configured to identify whether the optical pump source 104 is operational or has failed based on whether the feedback signal is present in the filtered signal. Here, the power indicated by the filtered signal satisfying (e.g., being greater than) the threshold may indicate that the feedback signal is present and that the optical pump source 104 is operational. Conversely, the power indicated by the filtered signal not satisfying the threshold may indicate that the feedback signal is absent and that the optical pump source 104 has failed (e.g., that the optical pump source 104 is off and is not emitting light). In some implementations, the feedback component 114 may be configured to identify an optical power of the optical pump source based on (e.g., as a function of) the power indicated by the filtered signal. In this way, a performance shift of the optical pump source 104 over time may be monitored. In general, the power of the feedback signal should be stable, and thus, the feedback component 114 may also be configured to identify an abnormality of the optical pump source 104 based on fluctuations of the power indicated by the filtered signal (e.g., a fluctuation that satisfies a threshold amount, a threshold quantity of fluctuations occurring within a particular time window, or the like).

In some implementations, the feedback component 114 may include one or more memories and/or one or more processors. The one or more processors may be configured to perform one or more operations of the feedback component 114, described herein. In some implementations, the feedback component 114 may include circuitry for performing one or more operations of the feedback component 114, described herein. For example, the feedback component 114 may include one or more comparators, one or more logic gates, or the like.

In some implementations, the optical amplifier system 100 may include a plurality of optical pump sources 104 (e.g., at least two optical pump sources 104, at least three optical pump sources 104, at least five optical pump sources 104, or the like), as shown. The optical pump sources 104 may be optically coupled to the optical amplifier 102 (e.g., to one or more optical amplifiers 102). For example, light emitted from the optical pump sources 104 may be combined and directed to the optical amplifier 102, or light emitted from the optical pump sources 104 may be directed to respective sections of the optical amplifier 102 (or to respective optical amplifiers 102). The optical amplifier system 100 may include a plurality of driver components 112 configured to respectively supply electrical currents to the optical pump sources 104, in a similar manner as described herein.

The optical pump sources 104 may be configured to emit light based on modulated electrical currents respectively supplied to the optical pump sources 104, in a similar manner as described herein. The modulated electrical currents may be based on the electrical currents supplied by the driver components 112. That is, the optical amplifier system 100 may be configured to apply modulations to the electrical currents, in a similar manner as described herein. In some implementations, the same modulations may be applied to electrical currents for the plurality of optical pump sources 104. In some implementations, different modulations may be applied to electrical currents for two or more optical pump sources 104.

In addition, the optical amplifier system 100 may include a plurality of detection components 106, as shown. The detection components 106 may be respectively optically coupled to the optical pump sources 104. For example, each detection component 106 may include a photodetector 108, and the photodetector 108 may be optically coupled to a corresponding optical pump source 104, in a similar manner as described herein. The detection components 106 may be configured to output respective filtered signals that are filtered with respect to one or more feedback signals that are to result from the modulated electrical currents, in a similar manner as described herein. For example, each detection component 106 (e.g., using a corresponding filter 110) may be configured to filter a signal generated by a photodetector 108 of the detection component 106 with respect to a feedback signal that is to result from a modulated electrical current supplied to a corresponding optical pump source 104.

Moreover, the feedback component 114 (e.g., a single feedback component 114 or respective feedback components 114 for the detection components 106) may be configured to identify respective states of the optical pump sources 104 based on whether feedback signals are present in the respective filtered signals. For example, the feedback component 114, to identify the respective states, may be configured to identify whether feedback signals are present in the respective filtered signals, in a similar manner as described herein. The feedback component 114 may be configured to identify one or more particular optical pump sources 104 that are operational or that have failed based on identifying whether the feedback signals are present in the respective filtered signals. For example, if a feedback signal is identified to be present in the filtered signal from a first detection component 106 for a first optical pump source 104, then the feedback component 114 may identify the first optical pump source 104 as being operational. However, if a feedback signal is not identified to be present in the filtered signal from a second detection component 106 for a second optical pump source 104, then the feedback component 114 may identify the second optical pump source 104 as having failed. In some implementations, the feedback component 114 may be configured to identify optical powers or abnormalities of the optical pump sources 104 based on powers of the respective filtered signals, in a similar manner as described herein.

While the description above is in terms of an optical amplifier that is optically pumped, in some implementations, the techniques and apparatuses described herein can be applied in connection with monitoring one or more optical sources that optically pump any optical fiber (e.g., an optical oscillator fiber), monitoring one or more optical sources that optically pump an optical coupler, monitoring a bank of laser diodes or other optical sources, or the like.

As indicated above, FIG. 1 is provided as an example. Other examples may differ from what is described with regard to FIG. 1.

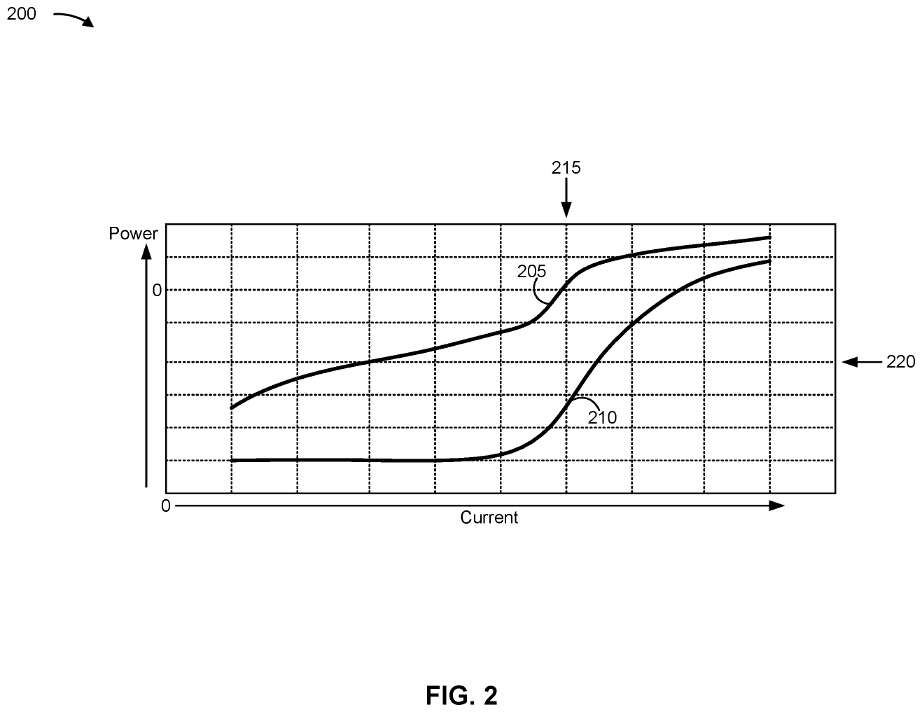

FIG. 2 is a diagram of an example plot 200 showing a relationship between optical pump source power and tone power. In particular, plot 200 shows the relationship between optical pump source power and tone power (e.g., tone power that is indicated by a filtered signal, as described herein) as a function of electrical current. Line 205 represents an output power of an optical pump source (e.g., an optical pump source 104), and line 210 represents a power of a tone (e.g., a tone in a signal of a detection component 106) that is based on a modulated electrical current supplied to the optical pump source. As shown in the plot 200, as current increases and approaches a threshold current 215 (e.g., a lasing threshold current) for the optical pump source, there is a sharp increase in tone power. In other words, as current increases to a threshold current for the optical pump source, a corresponding increase in tone power above a threshold 220 (e.g., −20 decibel-milliwatts (dBm)) indicates that the optical pump source is operational. Conversely, the current increasing to the threshold current for the optical pump source without an increase in tone power above the threshold 220 indicates that the optical pump source has failed (e.g., is not emitting light).

As indicated above, FIG. 2 is provided as an example. Other examples may differ from what is described with regard to FIG. 2.

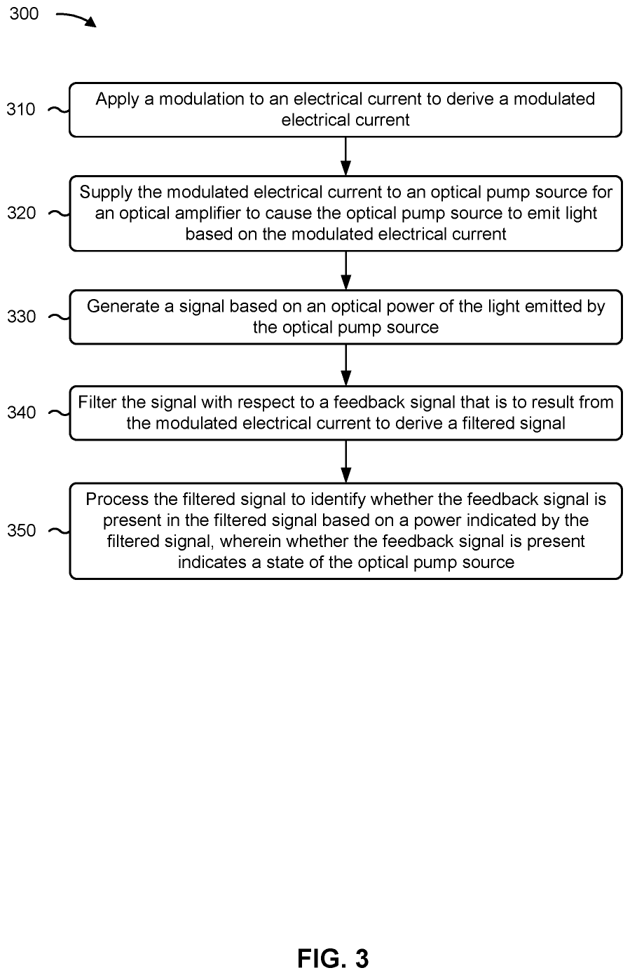

FIG. 3 is a flowchart of an example process 300 associated with monitoring an optical pump source. In some implementations, one or more process blocks of FIG. 3 are performed by a device (e.g., optical amplifier system 100). In some implementations, one or more process blocks of FIG. 3 are performed by another device or a group of devices separate from or including the device.

As shown in FIG. 3, process 300 may include applying a modulation to an electrical current to derive a modulated electrical current (block 310). For example, the device may apply a modulation to an electrical current to derive a modulated electrical current, as described above.

As further shown in FIG. 3, process 300 may include supplying the modulated electrical current to an optical pump source for an optical amplifier to cause the optical pump source to emit light based on the modulated electrical current (block 320). For example, the device may supply the modulated electrical current to an optical pump source for an optical amplifier to cause the optical pump source to emit light based on the modulated electrical current, as described above.

As further shown in FIG. 3, process 300 may include generating a signal based on an optical power of the light emitted by the optical pump source (block 330). For example, the device may generate a signal based on an optical power of the light emitted by the optical pump source, as described above.

As further shown in FIG. 3, process 300 may include filtering the signal with respect to a feedback signal that is to result from the modulated electrical current to derive a filtered signal (block 340). For example, the device may filter the signal with respect to a feedback signal that is to result from the modulated electrical current to derive a filtered signal, as described above.

As further shown in FIG. 3, process 300 may include processing the filtered signal to identify whether the feedback signal is present in the filtered signal based on a power indicated by the filtered signal, wherein whether the feedback signal is present indicates a state of the optical pump source (block 350). For example, the device may process the filtered signal to identify whether the feedback signal is present in the filtered signal based on a power indicated by the filtered signal, as described above. In some implementations, whether the feedback signal is present indicates a state of the optical pump source.

Process 300 may include additional implementations, such as any single implementation or any combination of implementations described below and/or in connection with one or more other processes described elsewhere herein.

In a first implementation, processing the filtered signal includes comparing the power indicated by the filtered signal to a threshold (e.g., threshold 220) to identify whether the feedback signal is present in the filtered signal.

In a second implementation, alone or in combination with the first implementation, process 300 includes identifying whether the optical pump source is operational or has failed based on whether the feedback signal is present in the filtered signal.

In a third implementation, alone or in combination with one or more of the first and second implementations, process 300 includes identifying an optical power of the optical pump source based on the power indicated by the filtered signal.

In a fourth implementation, alone or in combination with one or more of the first through third implementations, filtering the signal with respect to the feedback signal includes filtering the signal to pass a range of frequencies that includes a frequency of the feedback signal.

Although FIG. 3 shows example blocks of process 300, in some implementations, process 300 includes additional blocks, fewer blocks, different blocks, or differently arranged blocks than those depicted in FIG. 3. Additionally, or alternatively, two or more of the blocks of process 300 may be performed in parallel.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

As used herein, the term “component” is intended to be broadly construed as hardware, firmware, and/or a combination of hardware and software. It will be apparent that systems and/or methods described herein may be implemented in different forms of hardware, firmware, or a combination of hardware and software. The actual specialized control hardware or software code used to implement these systems and/or methods is not limiting of the implementations. Thus, the operation and behavior of the systems and/or methods are described herein without reference to specific software code—it being understood that software and hardware can be designed to implement the systems and/or methods based on the description herein.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “front,” “back,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. An optical amplifier system, comprising:
a rare-earth doped fiber amplifier (RDFA);
an optical pump source having a first end and a second end opposite the first end,
wherein the optical pump source is to emit light via the first end and the second end based on a modulated electrical current supplied to the optical pump source, and
wherein the first end of the optical pump source is optically coupled to the RDFA;
a detection component having a photodetector optically coupled to the second end of the optical pump source and a filter connected to the photodetector,
wherein the photodetector is configured to generate a signal based on light that is to be emitted via the second end of the optical pump source, and the filter is configured to output a filtered signal by filtering the signal from the photodetector with respect to a feedback signal that is to result from the modulated electrical current; and
a feedback component configured to identify whether the feedback signal is present in the filtered signal based on a power indicated by the filtered signal,
wherein whether the feedback signal is present indicates a state of the optical pump source.

2. The optical amplifier system of claim 1, wherein the feedback component is further configured to apply a modulation to an electrical current to derive the modulated electrical current.

3. The optical amplifier system of claim 1, wherein the feedback component is configured to identify whether the feedback signal is present in the filtered signal by comparing the power indicated by the filtered signal to a threshold.

4. The optical amplifier system of claim 1, wherein the feedback component is further configured to identify an optical power of the optical pump source based on the power indicated by the filtered signal.

5. The optical amplifier system of claim 1, wherein the optical pump source is a laser diode.

6. The optical amplifier system of claim 5, wherein the laser diode is edge emitting, and the first end is a front facet of the laser diode and the second end is a back facet of the laser diode.

7. The optical amplifier system of claim 1, wherein the first end of the optical pump source is optically coupled directly to the RDFA.

8. The optical amplifier system of claim 1, wherein an optical power of light emitted from the first end of the optical pump source is greater than an optical power of light emitted from the second end of the optical pump source.

9. The optical amplifier system of claim 1, wherein the filter includes a band-pass filter that is configured to pass a range of frequencies that includes a frequency of the feedback signal.

10. The optical amplifier system of claim 1, wherein a first signal-to-noise ratio (SNR) associated with the filtered signal is greater than a second SNR associated with the signal.

11. An optical amplifier system, comprising:
at least one optical amplifier;
a plurality of optical pump sources optically coupled to the at least one optical amplifier,
wherein the plurality of optical pump sources are configured to emit light based on modulated electrical currents respectively supplied to the plurality of optical pump sources;
a plurality of detection components respectively optically coupled to the plurality of optical pump sources, a detection component, of the plurality of detection components, including a photodetector optically coupled to an optical pump source, of the plurality of optical pump sources, and a filter connected to the photodetector,
wherein the photodetector is configured to generate a signal based on light that is to be emitted via the optical pump source, and the filter is configured to output a filtered signal by filtering the signal with respect to a feedback signal that is to result from a modulated electrical current supplied to the optical pump source; and
at least one feedback component configured to identify respective states of the plurality of optical pump sources based on filtered signals output by respective filters of the plurality of detection components.

12. The optical amplifier system of claim 11, wherein the at least one feedback component, to identify the respective states, is configured to identify whether respective feedback signals are present in the respective filtered signals.

13. The optical amplifier system of claim 11, wherein a state of the respective states indicates an operational state or a failure state.

14. The optical amplifier system of claim 11, further comprising:
a plurality of driver components configured to respectively supply electrical currents to the plurality of optical pump sources,
wherein the modulated electrical currents are based on the electrical currents.

15. The optical amplifier system of claim 11, wherein the optical pump source is to emit light via a first end of the optical pump source, and
wherein the detection component is optically coupled to a second end of the optical pump source that is opposite the first end.

16. A method, comprising:
applying, by a device, a modulation to an electrical current to derive a modulated electrical current;
supplying, by the device, the modulated electrical current to an optical pump source for an optical amplifier to cause the optical pump source to emit light based on the modulated electrical current;
generating, by the device using a photodetector, a signal based on an optical power of the light emitted by the optical pump source;
filtering, by the device using a filter, the signal with respect to a feedback signal that is to result from the modulated electrical current to derive a filtered signal; and
processing, by the device, the filtered signal to identify whether the feedback signal is present in the filtered signal based on a power indicated by the filtered signal,
wherein whether the feedback signal is present indicates a state of the optical pump source.

17. The method of claim 16, wherein processing the filtered signal comprises:
comparing the power indicated by the filtered signal to a threshold to identify whether the feedback signal is present in the filtered signal.

18. The method of claim 16, further comprising:
identifying whether the optical pump source is operational or has failed based on whether the feedback signal is present in the filtered signal.

19. The method of claim 16, further comprising:
identifying an optical power of the optical pump source based on the power indicated by the filtered signal.

20. The method of claim 16, wherein filtering the signal with respect to the feedback signal comprises:
filtering the signal to pass a range of frequencies that includes a frequency of the feedback signal.
